(19) United States
(12) Patent Application Publication
(10) Pub. No.: US 2009/0140415 A1
(43) Pub. Date: Jun. 4, 2009

(54) COMBINATION SUBSTRATE

(75) Inventor: Toru FURUTA, Ogaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: IBIDEN CO., LTD, Ogaki-shi (JP)

(21) Appl. No.: 12/163,150

(22) Filed: Jun. 27, 2008

Related U.S. Application Data
(60) Provisional application No. 60/991,118, filed on Nov. 29, 2007.

(51) Int. Cl. H01L 23/485

(52) U.S. Cl. 257/700; 257/E23.019

(57) ABSTRACT

A combination substrate includes a first substrate having wiring board mounting pads for installing a printed wiring board and connection pads on an opposite side of the wiring board mounting pads, a second substrate having package substrate mounting pads for mounting one or more package substrates and having connection pads on an opposite side of the package substrate mounting pads, a middle substrate positioned between the first substrate and the second substrate and including conductive members electrically connecting the connection pads on the first substrate and the connection pads on the second substrate, and a die positioned between the first substrate and the second substrate and mounted on one of the first substrate and the second substrate.

### CROSS-REFERENCE TO RELATED APPLICATIONS

The present application claims the benefits of priority to U.S. Applications No. 60/991,118, filed Nov. 29, 2007. The contents of that application are incorporated herein by reference in their entirety.

### BACKGROUND OF THE INVENTION

1. Field of the Invention

The present invention relates to a combination substrate on which to mount a package substrate with a mounted semiconductor element; especially to a combination substrate where the package substrate and a substrate are electrically connected in a POP (Package On Package) structured with at least two substrates.

2. Discussion of the Background

There is a demand for increased density in mounting electronic components. The background for such a demand is to secure mounting spaces in an area of a substrate limited by added functions or intensive functions. For example, in a cell phone, such a requirement is dealt with by forming a component, which formerly required a package substrate with two mounted IC chips, as a package substrate by laminating two IC chips and connecting the terminals of the IC chips and the substrate with wire bonding or the like; or as a multi-tier package by laminating a package onto a package, a so-called Package On Package. In Japanese Laid-Open Patent Publication 2004-273938, a laminated-type semiconductor device is disclosed where a semiconductor element is sandwiched between a first wiring substrate and a second wiring substrate, and connection between the first wiring substrate and the second wiring substrate is obtained through solder bumps. The contents of the foregoing publication are incorporated herein by reference in their entirety.

### SUMMARY OF THE INVENTION

According to one aspect of the present invention, a combination substrate includes a first substrate having a group of wiring board mounting pads for installing a printed wiring board and a group of connection pads on an opposite side of the wiring board mounting pads, a second substrate having a group of package substrate mounting pads for mounting one or more package substrates and having a group of connection pads on an opposite side of the package substrate mounting pads, a middle substrate positioned between the first substrate and the second substrate and including a group of conductive members electrically connecting the connection pads on the first substrate and the connection pads on the second substrate, and a die positioned between the first substrate and the second substrate and mounted on one of the first substrate and the second substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-1(D) are views illustrating the steps for manufacturing a combination substrate according to Example 1.

FIGS. 2(A)-2(C) are views illustrating the steps for manufacturing a combination substrate according to Example 1.

FIGS. 3(A)-3(C) are views illustrating the steps for manufacturing a combination substrate according to Example 1.

FIGS. 4(A)-4(G) are views illustrating the steps for manufacturing a combination substrate according to Example 1.

FIGS. 5(A)-5(C) are views illustrating the steps for manufacturing a combination substrate according to Example 1.

FIGS. 6(A)-6(B) are views illustrating the steps for manufacturing a combination substrate according to Example 1.

FIGS. 7(A)-7(F) are plan views illustrating the positions of pads for mounting a package substrate in a combination substrate according to Example 1.

FIG. 8 is a cross-sectional view illustrating a cross-section of a combination substrate according to Modification 1 to Example 1.

FIG. 9 is a cross-sectional view illustrating a cross-section of a combination substrate according to Modification 2 to Example 1.

FIGS. 10(A)-10(C) are views illustrating the steps for manufacturing a combination substrate according to Example 2.

FIGS. 11(A)-11(C) are views illustrating the steps for manufacturing a combination substrate according to Modification 1 to Example 2.

### DESCRIPTION OF THE EMBODIMENTS

The embodiments will now be described with reference to the accompanying drawings, wherein like reference numerals designate corresponding or identical elements throughout the various drawings.

### EXAMPLE 1

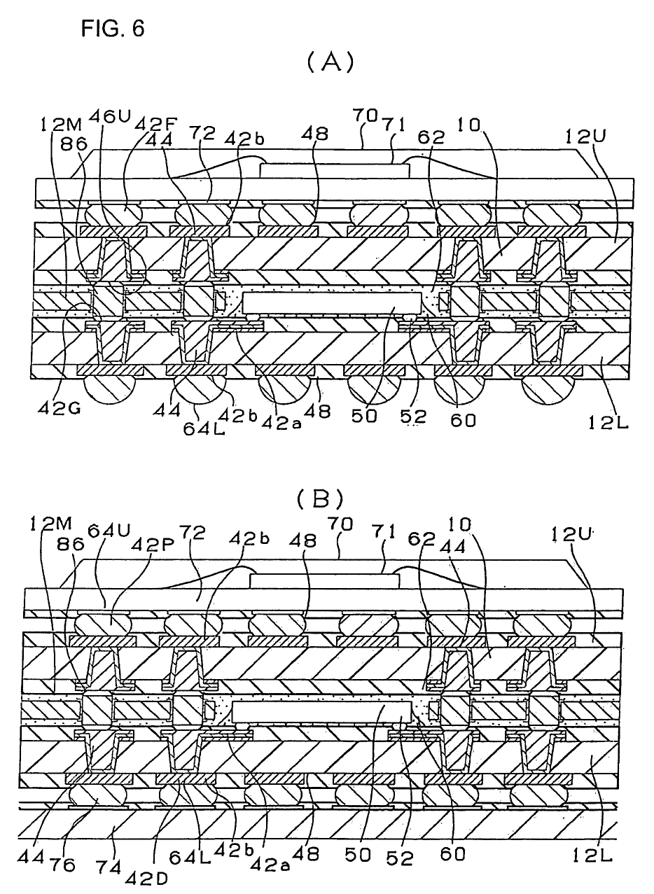

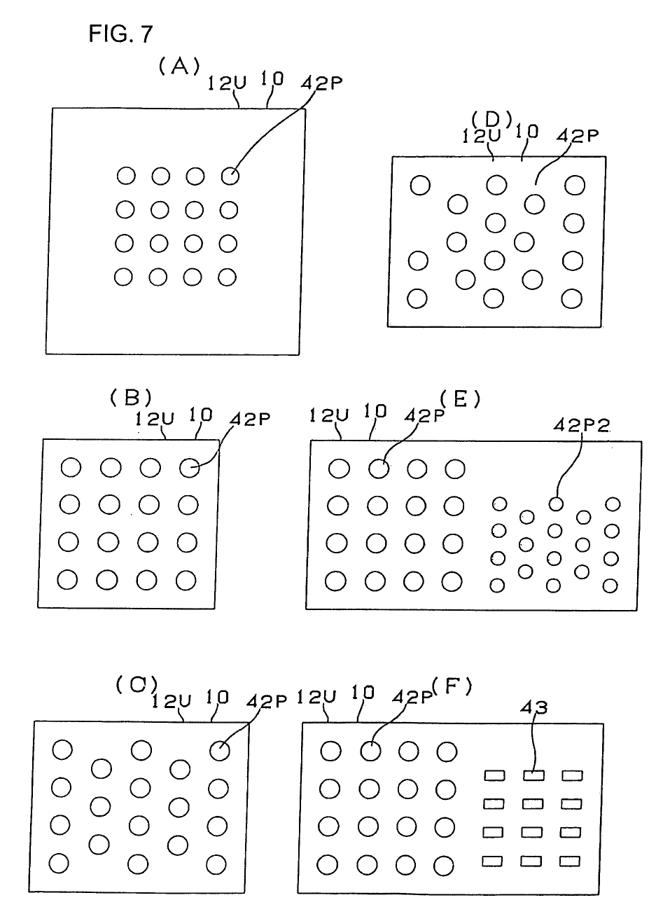

FIG. 6(A) shows a cross-sectional view of combination substrate 10 according to Example 1. Combination substrate 10 is structured with upper substrate (12U), interposer (12M) as an intermediate and lower substrate (12L). On upper substrate (12U), as shown in the plan view in FIG. 7(A) equivalent to a fragmentary view taken from the direction (a) in FIG. 6(A), a group of pads (42P) for connection to a package substrate is arranged in the center portion of upper substrate (12U). Likewise, on lower substrate (12L), a group of pads (42D) for connection to a printed wiring board is formed. On the top surface of lower substrate (12L), IC chip 50 is mounted. At lower substrate (12L), conductive circuit (42b) on the bottom surface and conductive circuit (42a) on the top surface are connected through vias 44, and IC chip 50 and conductive circuit (42b) on the top surface are connected through solder bumps 52. In openings (48a) of solder resist 48 for conductive circuit (42a) on the top surface of lower substrate (12L), pads (42G) for connection to the upper substrate are formed; and in openings (48a) of solder resist 48 for conductive circuit (42b) on the bottom surface, a group of pads (42D) for connection to a printed wiring board substrate is formed.

In the same manner, at upper substrate (12U), conductive circuit (42a) on the bottom surface and conductive circuit (42b) on the top surface are connected through vias 44. In openings (48a) of solder resist 48 for conductive circuit (42a) on the bottom surface of upper substrate (12U), pads (42F) for connection to the lower substrate are formed; and in openings (48a) of solder resist 48 for conductive circuit (42b) on the top surface, pads (42P) for connection to a package substrate are formed. Between lower substrate (12L) and IC chip 50, insulative resin underfill 60 is filled; and between upper substrate (12U) and lower substrate (12L), resin filling agent 62 is filled. Pads (42F) on the bottom surface of upper substrate (12U) and pads (42G) on the top surface of lower substrate (12L) are electrically connected by cylindrical metal posts 86 in interposer (12M). Metal posts 86 are formed, for example, of copper or copper alloy.

As shown in FIG. 6(B), on pads (42D) on the bottom surface of combination substrate 10, solder bumps (64L) or a BGA is arranged, then connected to a group of pads 76 on printed wiring board 74 so that combination substrate 10 is loaded onto printed wiring board 74.

In combination substrate 10 according to Example 1, through posts 86 fitted into through-holes 82 in interposer (12M), connection pads (42G) on lower substrate (12L) and connection pads (42F) on upper substrate (12U) are electrically connected. Accordingly, it is possible to obtain connection through posts 86 with a smaller diameter than solder bumps, and thus wiring may be arranged with a fine pitch. Also, since uniformly manufactured posts 86 are used, unlike solder bumps of varying sizes, heat is generated uniformly, thus high temperatures in spots may seldom be generated. Moreover, since interposer (12M) lies in between, the height between upper substrate (12U) and lower substrate (12L) may be adjusted, making it easier to secure electrical connectivity and reliability.

Also, between upper substrate (12U) and lower substrate (12L), resin filling agent 62 made of insulative resin is filled. Because of resin filling agent (underfill) 62, if heat is generated in parts of the semiconductor element or posts 86 that are used as power lines, warping does not occur in upper substrate (12U) and lower substrate (12L). Thus, ruptured wiring in the upper substrate and the lower substrate may be prevented. Also, the speed of degradation caused by humidity intruding from the conductive circuit or from outside is reduced, making it easier to secure reliability.

It is further preferred that the difference in the thermal expansion coefficients of resin filling agent (underfill) 62, upper substrate (12U) and lower substrate (12L) be small. By doing this, the thermal expansion coefficients of the resin filling agent (underfill), the upper substrate and the lower substrate become substantially close. Accordingly, the difference in thermal expansion of the underfill, the upper substrate and the lower substrate decreases, thus making it less likely for warping to occur in the upper substrate and lower substrate.

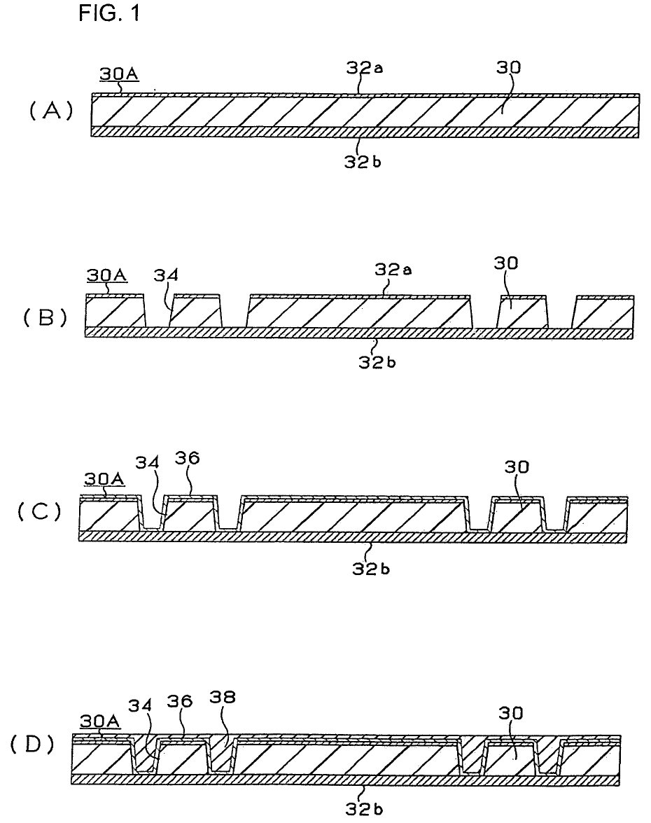

In the following, the steps for manufacturing a combination substrate according to Example 1 with reference to FIGS. 6(A) and 6(B) will be described by referring to FIGS. 1-5.

### A. Forming the Upper Substrate

### 1. Preparing the Base Material

Double-sided copper-clad laminate (30A) with copper foils (32a, 32b) laminated on both surfaces is prepared. As for insulative material 30, using such mainly containing resin material is preferred (FIG. 1(A)). As an example, glass-epoxy resin, polyimide resin, phenolic resin or BT resin may be listed. In addition, ceramic material or a metal substrate may also be used. The thickness of insulative material is preferred to be in the range of 60-300 μm. Also, the thickness of the copper foil is preferred to be in the range of 5-30 μm. The thicknesses of top and bottom copper foils (32a, 32b) may be the same, or their thicknesses may be different. A thicker copper foil is prepared and then, through a film-thinning step such as etching, the thickness of the copper foil may be adjusted properly.

### 2. Boring Holes by a Laser

To obtain electrical connection in double-sided copper-clad laminate (30A), a boring process is conducted by a laser to form openings 34 (FIG. 1(B)). In copper foil (32a) on the top surface, openings are bored by a direct process of beaming a laser directly. As for the laser, a CO2 laser or the like may be used. The beaming conditions are preferred to be in the following range: pulse energy 0.5-100 mJ, pulse width 1-100 μm, pulse interval 0.5 ms or longer, frequency 2,000-3,000 Hz, and number of shots 1-10. By such, copper-clad laminate (30A) with openings 34 reaching copper foil (32b) on the bottom surface, which receives the laser, is prepared.

### 3. Forming Plated Films

To obtain electrical continuity on the top and bottom of copper-clad laminate (30A) having openings 34, films are formed by plating. For plating, electroless plated film 36 is first formed (FIG. 1(C)), then an electrolytic plated film is formed. Here, the film may be formed by electroless plating only or by electrolytic plating only, or a film with multiple layers of such plating may be formed. If required, by filling with plated film 38, a field configuration may be formed (FIG. 1(D)). Accordingly, electrical connection between the top and bottom conductive layers of copper-clad substrate (30A) is secured.

### 4. Forming Wiring Patterns

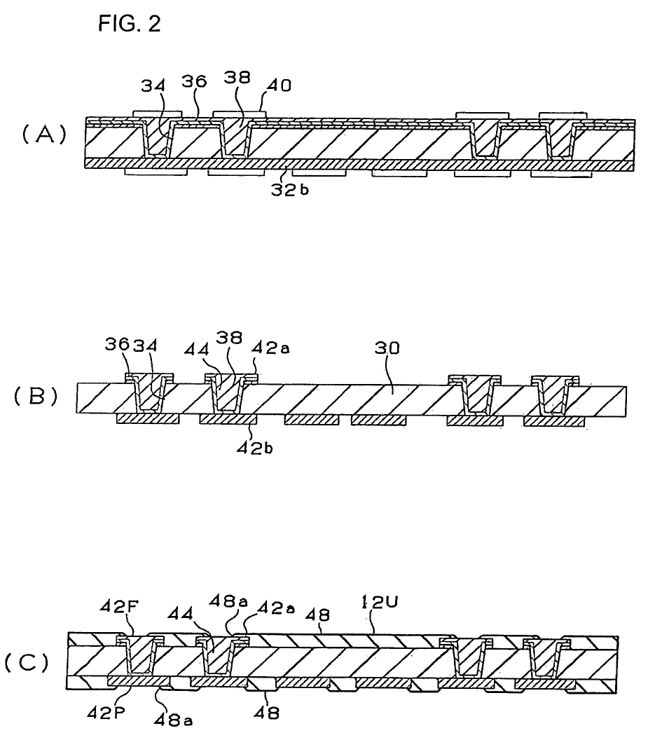

On the conductive layers after plated films are formed, resist layers are deposited. Masks with a drawn wiring pattern are placed on the resist layers, then after light-concentrating and developing treatments, portions 40 formed with a resist layer and portions formed without a resist layer are formed on conductive layer 38 and copper foil (32b) (FIG. 2(A)). Then, through an etching treatment using an etching solution containing iron (II) chloride or the like, conductive layers corresponding to the portions formed without a resist layer are removed. After that, by removing the resist layers using an alkaline solution or the like, double-sided circuit substrate 30 having wiring patterns (42a, 42b) and vias 44 is obtained (FIG. 2(B)).

On upper substrate (12U), solder-resist layer 48 may be formed to protect conductive circuit 42 if necessary (FIG. 2(C)). Here, at upper substrate (12U), on the surface facing the lower substrate (the lower portion in the drawing) a group of pads (42F) for connection to the lower substrate is formed in openings (48a) of solder-resist layer 48. On the surface opposite the surface facing the lower substrate (the upper portion in the drawing), a group of pads (42P) for connection to a package substrate is formed in openings (48a) of solder-resist layer 48.

### B. Forming the Lower Substrate

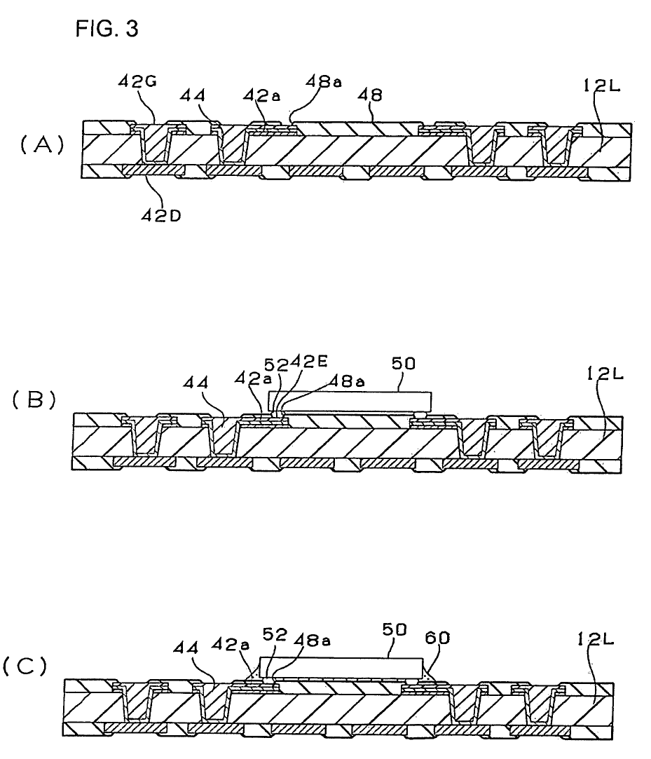

Steps 1-5 are the same as in the steps for the upper substrate (FIG. 3(A)).

### 6. Mounting an IC Chip

Solder bumps 52 are formed on IC chip-mounting pads (42E) of lower substrate (12L). IC chip 50 is mounted by flip-chip mounting through a reflow process on solder bumps 52 (FIG. 3(C)). Then, in the gap between IC chip 50 and lower substrate (12L), underfill 60 is filled (FIG. 3(C)). In doing so, a mounting substrate with mounted IC chip 50 (lower substrate (12L)) is formed. As for underfill 60, either thermosetting resin or photosensitive resin may be used. More specifically, one or more resins such as epoxy resin, polyimide resin, phenolic resin or the like may be used. In such a resin, inorganic particles or the like may be contained. Also, instead of mounting by flip-chip, mounting by wire bonding followed by sealing may be employed. In addition, two or more IC chips may be mounted, or passive components such as a capacitor may be loaded together with the IC chip.

### C. Forming an Interposer

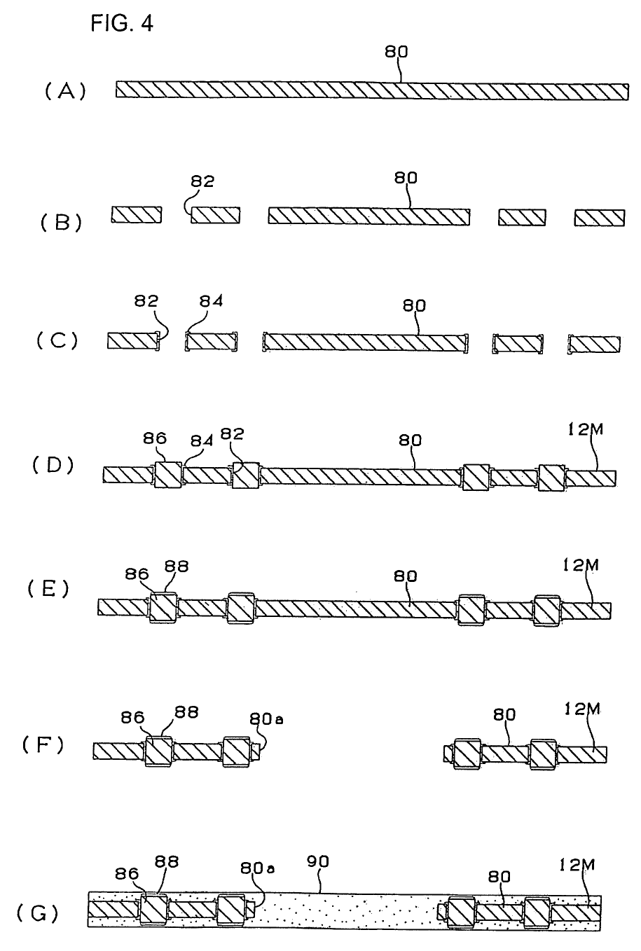

Insulative material 80 is prepared (FIG. 4(A)). Openings 82 penetrating insulative material 80 are formed (FIG. 4(B)) and conductive layers 84 are formed in openings 82 (FIG. 4(C)). Conductive layers 84 are formed by through-holes, vias and post-implants. For the conductive layers, metals such as copper, nickel or noble metals may be used.

As an example, there is a method to fill posts with implants. An insulative substrate having conductive layers formed by copper foil, plating or the like on both surfaces is prepared. Openings for through-holes are bored in the insulative substrate using a drill or a laser. Then, resist layers are provided on the entire surfaces of the conductive layers, and masks with a drawn wiring pattern are placed. After that, through exposure to light and development, then through an etching treatment, patterns for an interposer are formed. Then, if necessary, solder-resist layers may be formed or external configuration processing (unit processing for the interposer) may be conducted. By such, an insulative substrate having openings for implants is prepared.

Implant material to form implant posts is prepared. The thickness (height) is preferred to be thicker than the insulative substrate. Beneath the implant material, a lower jig for implant processing is placed in advance. Here, on the implant material, an upper jig with projections for piercing is placed. The upper jig pierces to the midway point of the implant material.

The pierced implant material is inserted in openings 82 of insulative substrate 80 prepared above, then pounded in. Accordingly, conductive members (metal posts) 86 penetrating the insulative substrate are formed (FIG. 4(D)). Then, the implant material is separated and the height of posts 86 protruding beyond insulative substrate 80 is aligned. In doing so, insulative substrate 80, which is interposer (12M), obtains conductive members (posts) 86, which enable electrical connection between the top and bottom, and whose heights protruding beyond insulative substrate 80 are substantially the same. Here, if required, adhesive agent 88 may be applied to anchor posts 86, which are conductive layers (FIG. 4(E)). In addition, at the tips of the conductive layers, a process to prevent oxidation or to improve the connection to the conductive layers of the substrate (forming roughened surfaces, mirror surface treatment, etc.) may be conducted. Further, open holes (80a) may be formed to prevent interference with an IC chip (FIG. 4(F)). In doing so, interposer (12M) lying between the upper substrate and lower substrate may be prepared.

### C. Forming a Laminated Substrate

### 1. Aligning the Lower Substrate and the Upper Substrate

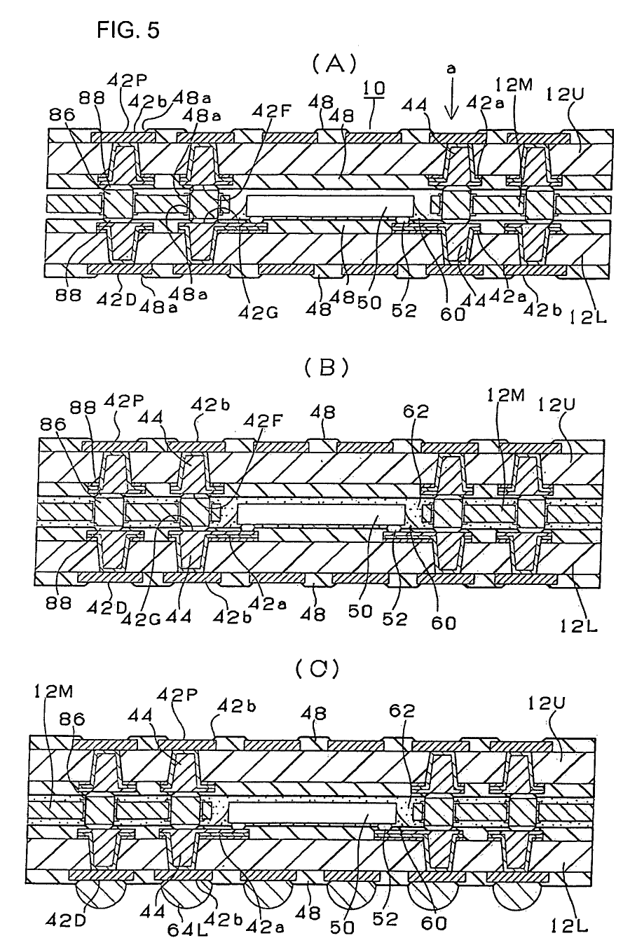

Circuit (pads) (42G) of lower substrate (12L), posts 86 of interposer (12M) and circuit (pads) (42F) of upper substrate (12U) are aligned (FIG. 5(A)). Here, circuit portions (42G) of lower substrate (12L) come in contact with posts 86 of interposer (12M); and circuit portions (42F) of upper substrate (12U) come in contact with posts 86 of interposer (12M). By such, upper substrate (12U) and lower substrate (12L) are electrically connected through interposer (12M). Posts 86 of interposer (12M) and conductive layers (42G, 42F) of each substrate may be connected using solder or the like as conductive adhesive agent 88. Here, if the upper substrate and the lower substrate are seen from the central portion of the interposer as an axis, the circuit portions at the connection show a mirror structure (a top-bottom symmetrical structure).

### 2. Filling Resin Between the Substrates

Filling resin 62 is filled between upper substrate (12U) and lower substrate (12L) (FIG. 5(B)). In such a case, the edge surfaces of filling resin 62 are preferred to be configured straight along the substrate. As for the resin to be filled between the substrates, either thermosetting resin or photosensitive resin may be used. More specifically, one or more kinds of resins such as epoxy resin, polyimide resin or phenolic resin may be used. Those resins may contain inorganic particles or the like, and may be the same resin as or a different resin from the underfill. Here, instead of filling with resin, as shown in FIG. 4(G), resin 90 may be applied on both surfaces of interposer (12M), and the gap between upper substrate (12U) and lower substrate (12L) may be sealed by resin 90.

According to requirements, solder bumps (64L) may be formed on pads (42D) of lower substrate (12L) (FIG. 5(C)). On a group of pads (42P) on the top portion of upper substrate (12U), package substrate 70 with built-in or mounted IC chip 71 may be mounted (FIG. 6(A)). By doing so, a laminated structure of a package substrate having two or more IC chips (50, 71) is obtained. Here, for external terminals, solder bumps or a BGA was used, but connection pins (PGA) may also be used. Then, through solder bumps 64 formed on a group of pads (42L) of lower substrate (12L) or a BGA, combination substrate 10 is connected to printed wiring board 74 by connecting it to pads 76 of printed wiring board 74 (FIG. 6(B)).

In the above example described with reference to FIG. 7(A), a group of pads (42P) for mounting a package substrate may be made circular and arranged in the center portion of upper substrate (12U). By doing so, a package substrate having external terminals such as a BGA may be loaded.

As shown in FIGS. 7(B) and 7(C), a group of pads (42P) for mounting a package substrate may be arranged substantially on the entire surface of upper substrate (12U). By doing so, a package substrate having external terminals such as a BGA arranged in full grid may be loaded.

As shown in FIGS. 7(B) and 7(C), a group of pads (42P) for mounting a package substrate may be arranged orderly so as to keep a constant distance from each other.

As shown in FIG. 7(B), a group (P) of pads 42 for mounting a package substrate may be arranged in matrix.

As shown in FIG. 7(C), a group of pads (42P) for mounting a package substrate may be arranged zigzag.

As shown in FIG. 7(D), pads (42P) for mounting a package substrate may be arranged at random. Furthermore, to mount two or more package substrates, pads for mounting a package substrate may be two kinds of pads (42P, 42P2). Moreover, as shown in FIG. 7(F), upper substrate (12U) may have pads 43 for mounting an electronic component as well as pads (42P). On the upper substrate, a package substrate with a mounted IC chip and a passive component such as a capacitor may be loaded together.

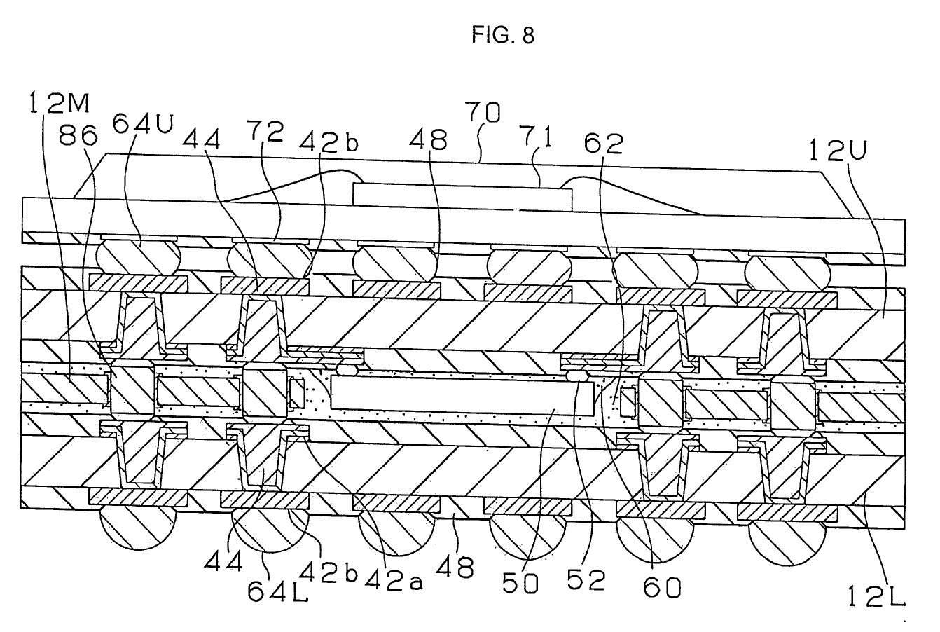

FIG. 8 shows a combination substrate according to Modification 1 to Example 1. In Example 1, as shown in FIG. 6(A), IC chip 50 was mounted on the top surface of lower substrate (12L). Instead, as shown in FIG. 8, IC chip 50 may also be mounted on the bottom surface of upper substrate (12U).

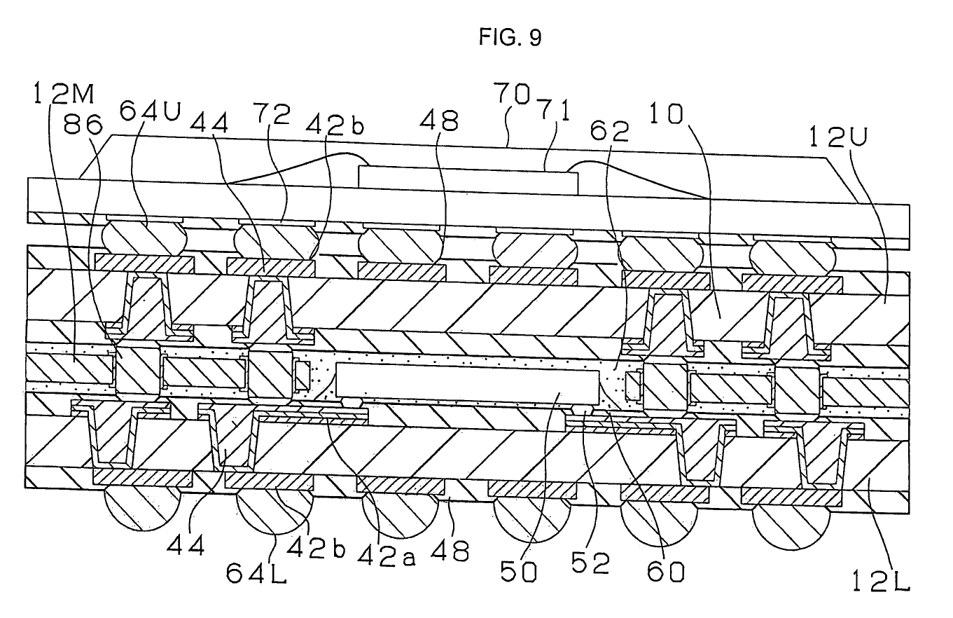

FIG. 9 shows a combination substrate according to Modification 2 to Example 1. In Example 1, upper substrate (12U) and lower substrate (12L) are arranged in a mirror image structure. Instead, as shown in FIG. 9, vias 66 and circuit (42b) of lower substrate (12L) may be arranged so as to spread toward the periphery (fan out).

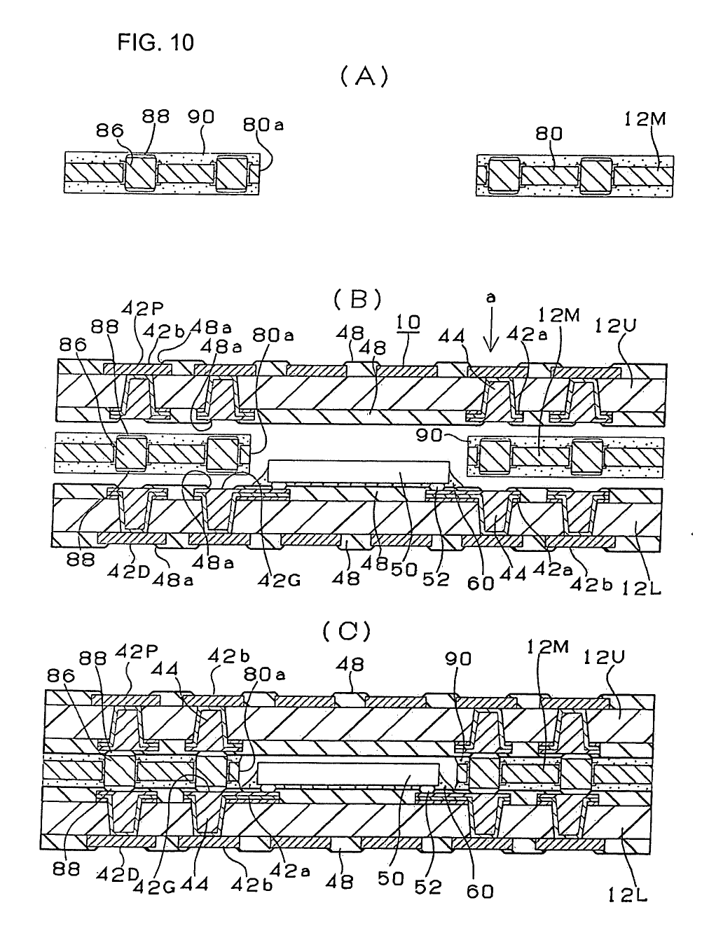

FIG. 10 show a combination substrate according to Example 2. In Example 1, interiors of open holes (80a) of interposer (12M) are filled with underfill 62 or resin 90. In contrast, as shown in FIG. 10(C), Example 2 has a structure so as not to fill the interiors of open holes (80a) of interposer (12M) with resin 90. Here, since the interiors of open holes (80a) of interposer (12M) are not filled with resin 90, occurrence of cracks at the interface (especially at the corners of the IC chip) between lower substrate (12L) and mounted IC chip 50 may be suppressed.

In Example 2, as shown in FIG. 10(A), non-flow type underfill 90 is applied on both surfaces of interposer (12M) excluding open holes (80a). As shown in FIG. 10(B), lower substrate (12L), interposer (12M) and upper substrate (12U) are aligned so as to be laminated as shown in FIG. 10(C). At that time, the flow of underfill 90 into openings (80a) is kept to a minimum.

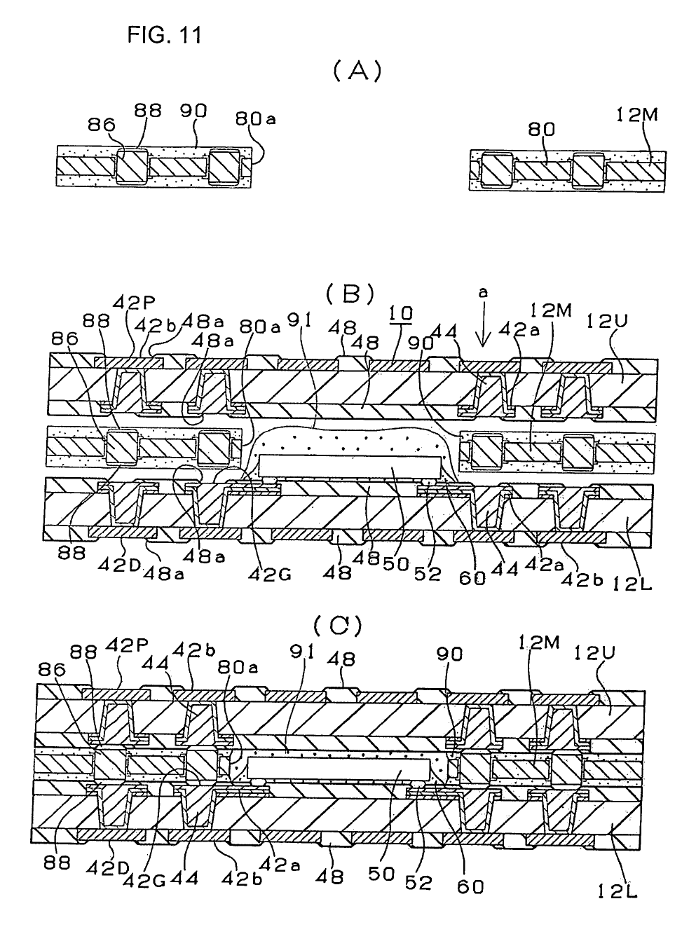

FIG. 11 show a combination substrate according to Modification 1 to Example 2. Example 2, as described above with reference to FIG. 10(C), was structured so as not to fill the interiors of open holes (80a) of interposer (12M) with underfill 90. In contrast, according to Modification 1 to Example 2, the interiors of open holes (80a) are filled with resin 91 which is less elastic than the underfill. Therefore, occurrence of cracks at the interface (especially at the angles of the IC chip) between lower substrate (12L) and mounted IC chip 50 may be suppressed.

In Example 2, as shown in FIG. 10(A), non-flow type underfill 90 is applied on both surfaces of interposer (12M) excluding open holes (80a), and as shown in FIG. 10(B), on IC chip 50 on lower substrate (12L), resin 90 with low elasticity is applied. Then, interposer (12M) and upper substrate (12U) are aligned so as to be laminated as shown in FIG. 10(C). Here, resin 91 with low elasticity is filled in openings (80a) of interposer (12M).

According to the foregoing embodiments of the present invention, a combination substrate is structured with a lower substrate which is to be installed on a printed wiring board, and an upper substrate which is to be installed on the upper surface of the lower substrate and on which to mount a package substrate; and on the surface of the lower substrate facing the upper substrate, or on the surface of the upper substrate facing the lower substrate, a die is mounted. The combination substrate has the following technical features: The lower substrate has connection pads for electrical connection to the upper substrate on the surface facing the upper substrate, and mounting pads for installation on the printed wiring board on the surface opposite the surface facing the upper substrate; the upper substrate has connection pads for electrical connection to the lower substrate on the surface facing the lower substrate, and mounting pads for installation of a package substrate on the surface opposite the surface facing the lower substrate; and a middle substrate positioned between the upper substrate and the lower substrate has conductive members electrically connecting the connection pads on the lower substrate and the connection pads on the upper substrate.

In the combination substrate, since a middle substrate lies in between, the height between the upper substrate and the lower substrate may be adjusted, making it easier to secure electrical connectivity and reliability.

Conductive members are preferred to be formed post-shaped with metal and fitted into openings in the middle substrate. Since the post-shaped conductive members electrically connect the connection pads on the lower substrate and the connection pads on the upper substrate, it is possible to obtain connection through conductive members whose diameters are smaller than those of solder bumps. Accordingly, wiring may be arranged with a fine pitch. Also, since uniformly manufactured post-shaped conductive members are used, unlike solder bumps of varying sizes, heat is generated uniformly, thus high temperatures in spots may seldom be generated. In addition, underfill is preferred to be filled between the upper substrate and the lower substrate. Because of the underfill, if heat is generated in spots at the semiconductor element or at the post-shaped conductive members that are used as power lines, warping does not occur and ruptured wiring in the upper substrate and lower substrate may be prevented. Also, the speed of degradation caused by humidity intruding from a conductive circuit or from outside is reduced, and thus reliability may be easily achieved.

Moreover, the mounting pads may be arranged substantially on the entire surface of the upper substrate. The mounting pads may be arranged orderly by keeping them a constant distance from each other. The mounting pads may be arranged in matrix or zigzag. The mounting pads may be arranged at random. The mounting pads may be the pads for mounting two or more package substrates. The mounting pads are preferred to be a circular shape. In such a case, circular shape includes circular, oval and quasi-circular. On the surface of the upper substrate, opposite the surface facing the lower substrate, pads for mounting an electronic component may be arranged.

Obviously, numerous modifications and variations of the present invention are possible in light of the above teachings. It is therefore to be understood that within the scope of the appended claims, the invention may be practiced otherwise than as specifically described herein.

What is claimed as new and desired to be secured by Letters Patent of the United States is:

1. A combination substrate comprising:
a first substrate having a plurality of wiring board mounting pads for installing a printed wiring board and a plurality of connection pads on an opposite side of the wiring board mounting pads;
a second substrate having a plurality of package substrate mounting pads for mounting at least one package substrate and having a plurality of connection pads on an opposite side of the package substrate mounting pads;
a middle substrate positioned between the first substrate and the second substrate and including a plurality of conductive members electrically connecting the connection pads on the first substrate and the connection pads on the second substrate; and
a die positioned between the first substrate and the second substrate and mounted on one of the first substrate and the second substrate.

2. The combination substrate according to claim 1, wherein the conductive members comprises a metal material with a post-shape and formed in a plurality of through-holes in the middle substrate, respectively.

3. The combination substrate according to claim 1, further comprises an underfill filled between the first substrate and the second substrate.

4. The combination substrate according to claim 1, wherein the wiring board mounting pads are positioned on substantially an entire surface of the first substrate.

5. The combination substrate according to claim 1, wherein the wiring board mounting pads are positioned at a constant distance from each other.

6. The combination substrate according to claim 1, wherein the wiring board mounting pads are positioned in one of a matrix pattern and a zigzag pattern.

7. The combination substrate according to claim 1, wherein the wiring board mounting pads are positioned at random.

8. The combination substrate according to claim 1, wherein the package substrate mounting pads are positioned to mount a plurality of package substrates.

9. The combination substrate according to claim 1, wherein the wiring board mounting pads has a circular shape.

10. The combination substrate according to claim 1, wherein the first substrate further comprises a plurality of pads for mounting a passive component on a side of the wiring board mounting pads.

11. The combination substrate according to claim 1, further comprising an underfill filled between the first and second substrates and the middle substrate.

12. The combination substrate according to claim 11, wherein the middle substrate has a plurality of openings to prevent interference with the die, and the underfill is not filled in the openings.

13. The combination substrate according to claim 11, wherein the middle substrate has a plurality of openings to prevent interference with the die, and the openings are filled with resin which is less elastic than the underfill.

14. The combination substrate according to claim 1, wherein the middle substrate comprises an interposer.

15. The combination substrate according to claim 1, wherein the die comprises an IC chip.

16. The combination substrate according to claim 2, further comprising an underfill filled between the first and second substrates and the middle substrate.
